(19) United States
(12) Patent Application Publication
(10) Pub. No.: US 2026/0083026 A1
(43) Pub. Date: Mar. 19, 2026

(54) CONDUCTIVE PILLAR BUMPS FOR INTEGRATED CIRCUITS

(71) Applicant: TEXAS INSTRUMENTS INCORPORATED, DALLAS, TX (US)

(72) Inventors: Jomari AUSTRIA, MABALACAT CITY (PH); Jeffrey S. SOLAS, ILOILO CITY (PH); Jose Arvin M. PLOMANTES, DAGUPAN (PH)

(21) Appl. No.: 18/886,354

(22) Filed: Sep. 16, 2024

(51) Int. Cl. H01L 23/498; H01L 21/768

(52) U.S. Cl. CPC H10W 90/701; H10W 20/043; H10W 20/077

(57) ABSTRACT

A described example includes a method for fabricating an integrated circuit (IC) device. The method includes forming a barrier layer over a surface of a semiconductor substrate and a conductive terminal in the surface. The method also includes forming a conductive seed layer over the barrier layer and at least a portion of the surface of the semiconductor substrate. The method also includes forming a conductive post over the seed layer, in which the conductive post includes a sidewall portion extending from a proximal end at the seed layer to terminate in a distal end spaced apart from the seed layer. The method also includes forming a passivation layer over the surface of the semiconductor substrate and surrounding the sidewall portion of the conductive post.

### TECHNICAL FIELD

This description relates generally to integrated circuits and fabrication thereof, and more particularly, integrated circuits and to methods of forming integrated circuits with conductive pillar bumps.

### BACKGROUND

Integrated circuit (IC) packages have long been implemented in computer devices for providing increasingly compact circuits in computer products. Wafer-level packaging (WLP) is a process in IC manufacturing in which packaging components are attached to the ICs before dicing the wafer into respective IC dies or chips. WLP can be used to form various types of ICs, including flip-chip devices and/or quad flat no-lead (QFN) packages. Such devices may include conductive posts that provide electrical contact to associated contact pads on a printed circuit board (PCB). In some ICs solder bumps (e.g., of flowable solder) are formed on the conductive posts for making connections during reflow to other circuitry.

### SUMMARY

One example includes a method for fabricating an integrated circuit (IC) device. The method includes forming a barrier layer over a surface of a semiconductor substrate and a conductive terminal in the surface. The method also includes forming a conductive seed layer over the barrier layer and at least a portion of the surface of the semiconductor substrate. The method also includes forming a conductive post over the seed layer, in which the conductive post includes a sidewall portion extending from a proximal end at the seed layer to terminate in a distal end spaced apart from the seed layer. The method also includes forming a passivation layer over the surface of the semiconductor substrate and surrounding the sidewall portion of the conductive post.

Another example described herein relates to an integrated circuit device. The integrated circuit device includes a semiconductor substrate, a barrier layer, a conductive post, and a passivation layer. The semiconductor substrate has a surface that includes a conductive terminal. The barrier layer is over the conductive terminal, in which the barrier layer has an outer periphery that is aligned with or spaced inwardly from an outer periphery of the conductive terminal. The conductive post extends outwardly from the barrier layer to terminate in a distal end, in which the conductive post includes a sidewall having an outer periphery that is substantially aligned with or spaced inwardly from the outer periphery of the barrier layer. The passivation layer is over the surface and surrounding a proximal portion of the conductive post, in which the passivation layer does not directly contact the conductive terminal.

Another example described herein relates to an integrated circuit device that includes a semiconductor substrate, a barrier layer, a plurality of conductive posts, a solder bump, and a passivation layer. The semiconductor substrate includes a plurality of conductive pads distributed across a surface of the semiconductor substrate within a conductive layer of the semiconductor substrate. The barrier layer includes a plurality of barrier members, in which each of the barrier members is over a respective one of the conductive pads, and each of the barrier members has an outer periphery that is substantially aligned with an outer periphery of the respective conductive pad. Each of the conductive posts is over a respective one of the conductive pads and extends outwardly from a proximal end at the barrier layer to terminate in a distal end thereof over the respective conductive pad, and each conductive post has a periphery at the proximal end thereof that is substantially aligned with or spaced radially inwardly from the outer periphery of the respective conductive pad. A respective solder bump is on the distal end of each conductive post, in which each respective solder bump is coupled to the respective conductive pad through a respective conductive post and a respective barrier member. The passivation layer is over the surface of the semiconductor substrate surrounding a proximal portion of each of the conductive posts, in which the passivation layer does not directly contact the conductive pad.

### BRIEF DESCRIPTION OF THE DRAWINGS

FIG. 1 depicts an example of part of an IC device.

FIG. 2 is a flow diagram illustrating an example method for forming an IC device.

FIGS. 3-11 are examples of part of an IC device at different stages of the fabrication process.

FIG. 12 is a plan view of an example IC device having bumps formed on a surface of the IC device.

### DETAILED DESCRIPTION

This description relates generally to integrated circuit fabrication systems, and more particularly to a fabrication process for forming conductive posts for integrated circuit (IC) devices. In some integrated circuits (ICs), the IC package can be formed as a flip-chip package and/or quad flat no-lead (QFN) package that may include conductive posts that extend from conductive terminals of the IC package to provide electrical contact to associated contact pads on a printed circuit board (PCB). Such IC packages often include a passivation layer, such as polyimide (PI), that surrounds the conductive post(s), such as to provide a sturdy dielectric material to protect and shield the device. In some cases, the passivation layer can interact with the conductive terminal of the IC, such as through a thin film, leading to an increased resistance between the bump and the conductive terminal. The ICs and methods described herein thus can reduce the resistance between the bump and the conductive terminal by forming the passivation layer after forming the conductive posts.

As an example, a barrier layer (e.g., titanium (Ti) or titanium tungsten (TiW)) is formed over a conductive terminal (e.g., a conductive pad on an IC die) that is formed in a respective surface of a semiconductor substrate. A conductive seed layer can be formed over the barrier layer and at least a portion of the surface of the semiconductor substrate, and one or more conductive posts are formed over the seed layer (e.g., by a plating process). For example, each conductive post is coupled to a respective conductive terminal and includes a sidewall portion extending from a proximal end at the seed layer to terminate in a distal end spaced apart from the seed layer and overlying the respective conductive terminal. A passivation layer is formed (e.g., through a mask or reticle) over the surface of the semiconductor substrate surrounding the sidewall portion of the conductive post, which can be offset from the conductive post. A solder bump can be formed on the distal end of each conductive post. In some examples, a gap can form (e.g., responsive to curing the passivation layer) between a distal portion of the passivation layer and an outer periphery of the conductive post(s). As described herein, the passivation layer does not contact the conductive terminal (e.g., pad structure) in the semiconductor substrate and the resistance between solder bump and the conductive terminal can be reduced (e.g., providing higher conductivity). The distal end of the conductive post can have an increased surface area to receive the solder bump, which can increase the shear strength of the bump.

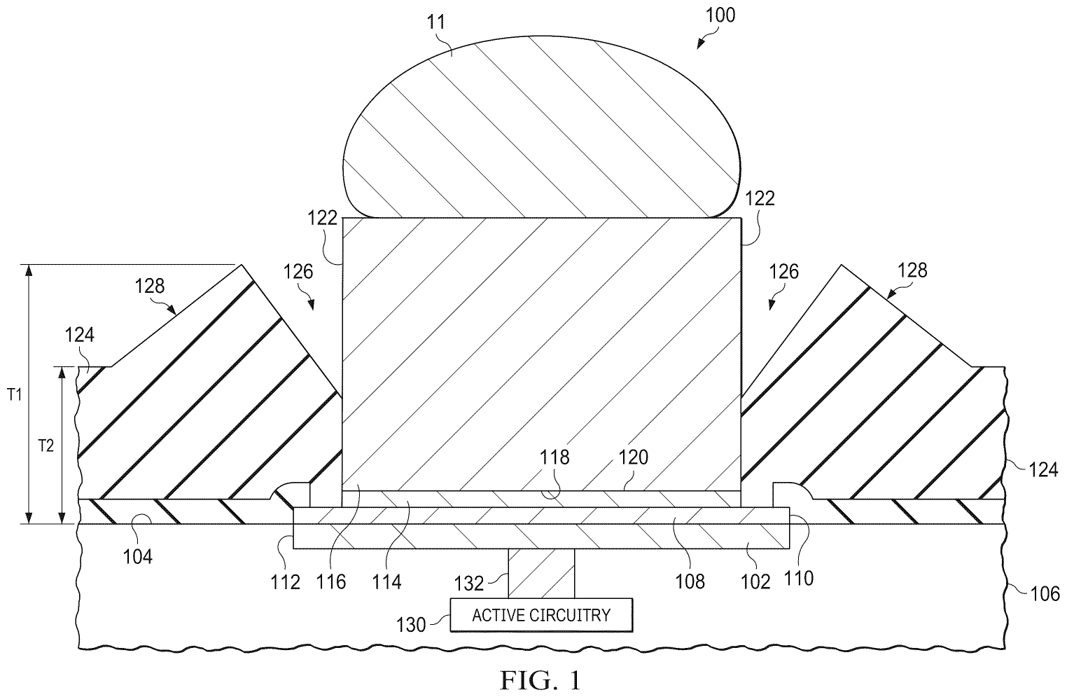

FIG. 1 depicts an example of part of an IC device 100. The IC device 100 can be implemented in any of a variety of applications, such as high-voltage circuit applications that are implemented on a flip-chip or quad flat no-lead (QFN) package design. The IC device 100 is demonstrated in the example of FIG. 1 in a cross-sectional view to show relative locations of respective layers. The IC device 100 is demonstrated by way of example and is not intended to be shown to scale.

The IC device 100 includes a conductive terminal 102 in a respective surface 104 of a semiconductor substrate 106. For example, the semiconductor substrate 106 is a semiconductor die of a packaged IC device and the conductive terminal is one of a number of conductive terminals (e.g., conductive pads of a metal top layer) distributed across the semiconductor die. The IC device 100 also includes a barrier layer 108 over the conductive terminal 102. In an example, the barrier layer 108 defines a barrier member having an outer periphery 110 that is substantially aligned with an outer periphery 112 of the conductive terminal 102. As described herein, the term “substantially aligned” with respect to the peripheries of the barrier member and the conductive terminal describes a spatial relationship between respective radially outer sidewall surfaces in which there is no overlap of one sidewall surface with respect to the other, in that no portion of an outer periphery of one sidewall surface extends beyond an outer periphery of the other surface. A respective barrier member can be provided over each of the conductive terminals 102 across the surface of the IC device 100. In some examples, the outer periphery 110 may be spaced inwardly or outwardly relative to the outer periphery 112 of the conductive terminal 102. The IC device 100 includes a seed layer 114 of a conductive material over the barrier layer 108. A conductive post 116 extends outwardly from the surface 104 of the semiconductor substrate 106 over the barrier layer to terminate in a distal end. In the example of FIG. 1, the conductive post has a proximal end 118 that contacts a distal surface 120 of the seed layer 114. The seed layer 114 and conductive post 116 can be formed of the same conductive material (e.g., copper). The conductive post 116 thus includes a sidewall 122 having an outer periphery that is aligned with or spaced inwardly from the outer periphery 110 of the barrier layer 108.

The IC device 100 also includes a passivation layer 124 over the surface 104 of the semiconductor substrate 106 surrounding a proximal portion of the conductive post 116. The passivation layer does not directly contact the conductive terminal. A portion 128 of the passivation layer 124 surrounding and adjacent to the conductive post 116 can have an increased thickness, shown at T1, compared to a thickness, shown at T2, of the passivation layer at locations away from the conductive post. The portion 128 of the passivation layer 124 further can be spaced apart radially from an adjacent portion of the sidewall 122 of the conductive post 116 to define a gap 126 between portion 128 and the adjacent sidewall 122. As described herein, for example, the gap 126 can be formed during shrinkage that occurs responsive to curing the passivation layer 124. The passivation layer 124 can be formed of an electrically insulating dielectric material, such as polyimide or another dielectric film.

The IC device 100 can also include active circuitry, schematically shown at 130, formed in the semiconductor substrate 106. Each conductive terminal 102 can be coupled to the active circuitry 130 through a respective conductive via 132 that extends through the substrate 106. Each via 132 can be formed of an electrically conductive material, such as copper, palladium, gold, silver, or other appropriate conductive metal or metal alloys with similar properties. The active circuitry 130 can be configured to perform any one or more functions according to application requirements, such as including control functions, power conversion, sensing or other functions.

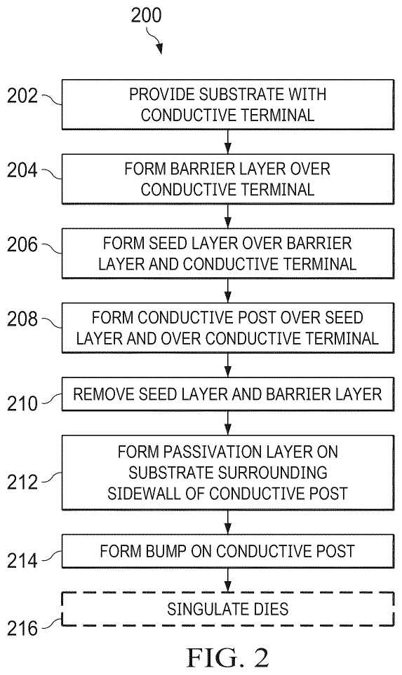

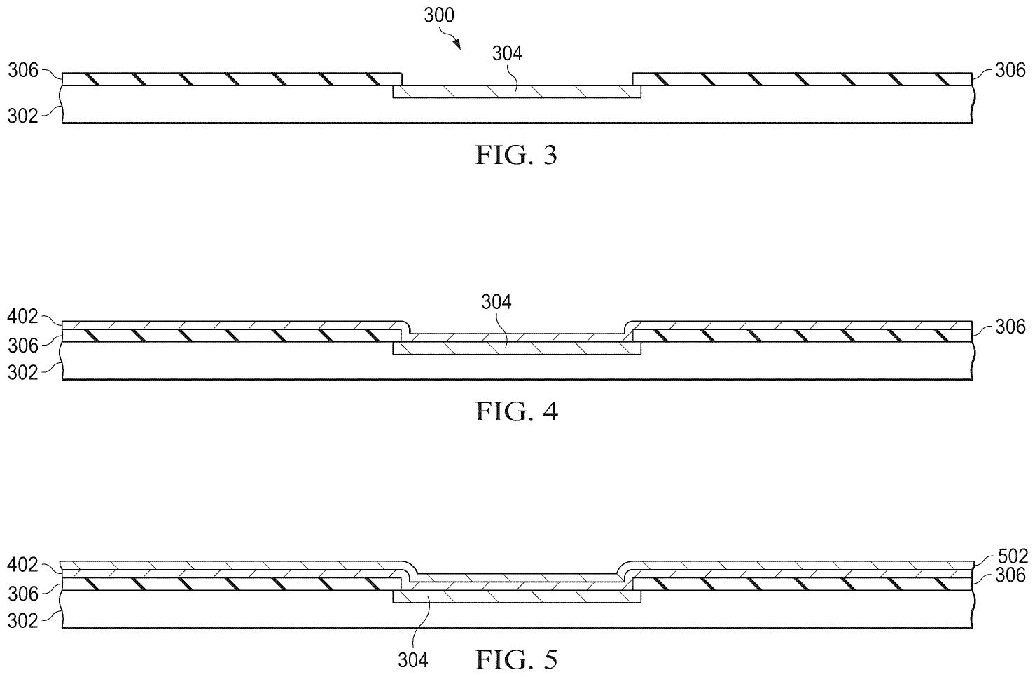

FIG. 2 is a flow diagram illustrating an example method 200 of fabricating an IC device, such as the IC device 100 of FIG. 1. Accordingly, the description of FIG. 2 refers to certain aspects of FIG. 1. For additional context, the method 200 of FIG. 2 will be described with respect to FIGS. 3-11, which are cross-sectional views depicting examples of part of an IC device at different stages of the fabrication method. While the method 200 of FIG. 2 is shown and described as a sequence of steps or actions, the method 200 is not limited by the illustrated order, as some aspects could occur in different orders and/or concurrently with other aspects from that shown and described herein. Moreover, not all illustrated features may be required to implement the method 200.

The method 200 begins at 202, in which a semiconductor substrate having a conductive terminal is provided. As described herein, the method 200 can be implemented as part of a wafer level packaging (WLP) process, such that the semiconductor substrate is one die among a number of semiconductor dies distributed across a semiconductor wafer prior to die singulation. In other examples, the method 200 can be implemented as a die-level packaging process after the wafer has been singulated into respective IC dies to which packaging components are added according to the method.

For example, as shown in FIG. 3, an IC device 300 includes a semiconductor die 302 having a conductive terminal 304 at a respective surface of the semiconductor die. For example, the conductive terminal 304 defines a conductive pad of an electrically conductive material (e.g., aluminum (Al)) that is fabricated in the wafer as part of a metal layer that includes a plurality of such pads distributed across the surface of each semiconductor die 302 to provide an input/output port for circuitry (e.g., active circuitry 130) of the semiconductor die 302. The semiconductor die 302 can be implemented as a metal-top IC, which the conductive pads distributed across the die define metal-top structures. In a wafer level packaging process, the semiconductor die defines one of a number of instances of the die across the wafer. A protective layer (e.g., an oxide, a nitride, or oxy-nitride layer) 306 can be formed over the surface of the semiconductor die 302. The protective layer 306 can cover surfaces of the die prior to implementing the bump process.

At 204, the method 200 includes forming a barrier layer over the conductive terminal and the surface of the semiconductor die. For example, as shown in FIG. 4, a barrier layer 402 is patterned over the conductive terminal 304 and the surface of the semiconductor die 302. As an example, the barrier layer 402 can be titanium (Ti) or titanium tungsten (TiW), and can be deposited by sputtering the material as a layer over the conductive terminal 304 and the surface of the semiconductor die 302. The barrier layer 402 thus can extend across the surface of the semiconductor die 302 to overlay each conductive terminal (e.g., pad) 304 the semiconductor die (e.g., to form respective instances of the barrier member 108).

At 206, the method 200 includes forming a conductive seed layer over the barrier layer and at least a portion of the surface of the semiconductor substrate. For example, as shown in FIG. 5, a seed layer 502 of a conductive material (e.g., copper (Cu) is formed over the barrier layer 402. The seed layer 502 provides a suitable electrically conductive surface for a subsequent electroplating operation. The seed layer 502 may include nickel (Ni) or copper (Cu), for example, and may be formed by a sputtering deposition process or an evaporation process.

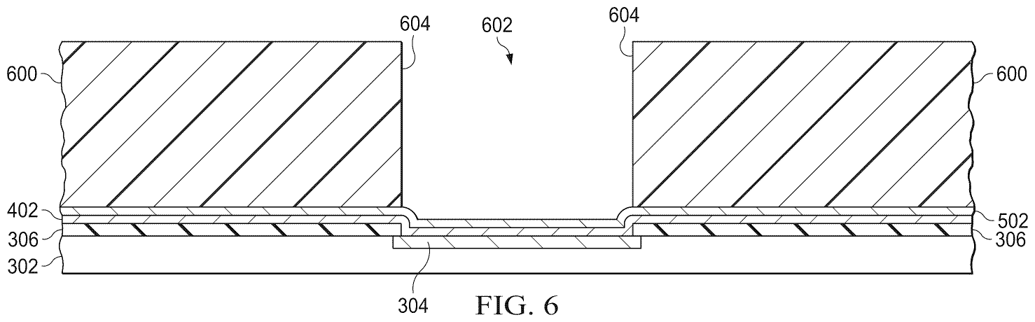

At 208, the method 200 includes forming a conductive post over the seed layer. The conductive post includes a sidewall portion extending from a proximal end at the seed layer to terminate in a distal end spaced apart from the seed layer. As shown in FIG. 6, a patterned mask 600 is formed over the seed layer 502, such as part of a photolithography process. For example, the mask 600 is formed of a layer of a photoresist material that is deposited over the seed layer 502, patterned, and etched to form an opening 602, which is defined by an inner periphery 604 of the photoresist material, overlying the conductive terminal 304. The inner periphery 604 of the opening 602 can have a uniform diameter and extend orthogonally from a surface of the exposed seed layer 502 substantially aligned with an outer periphery of the conductive terminal 304, such as shown in FIG. 6.

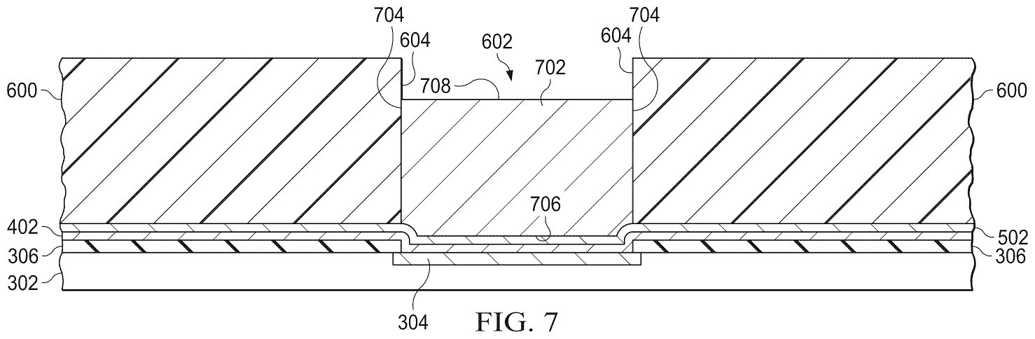

As shown in FIG. 7, a conductive material is applied in the opening 602 to form a conductive post 702. For example, the conductive post 702 is formed by plating a conductive material within the opening on the exposed portion of the seed layer 502. Thus, the conductive post 702 includes a sidewall portion 704 extending from a proximal end 706 at the seed layer 502 to terminate in a distal end 708 spaced apart from the seed layer. That is, the distal end 708 defines a surface of the conductive post 702 opposite the surface at the proximal end at the seed layer 502.

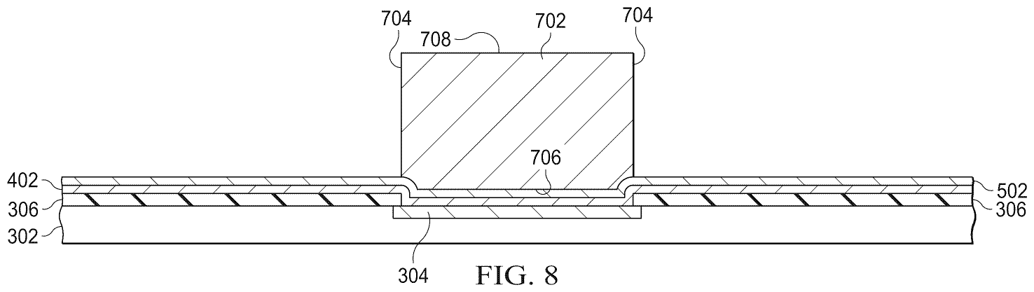

FIG. 8 shows the conductive post 702 after a remaining portion of the patterned mask 600 (a temporary mask) has been removed, such as by selectively etching the photoresist. For example, the patterned mask 600 can be removed by a chemical solvent or plasma and may further undergo a cleaning process to remove remaining residue. The shape and configuration of the inner periphery 604 of the patterned mask 600 defines the shape and configuration of the sidewall portion of the conductive post. In an example, the sidewall 704 of the conductive post 702 has a substantially uniform diameter between the proximal and distal ends 706 and 708. Other shapes and contours can be provided in other examples.

At 210, the method 200 includes removing exposed portions of the seed layer and barrier layer located radially outwardly from the conductive post from the semiconductor substrate. For example, the seed and barrier layers located radially outwardly from the sidewall of the conductive post can be removed from the semiconductor substrate to reveal the oxide layer 306. During such removal the conductive post 702 operates as mask to block removal and retain the portions of the seed layer 502 and barrier layer 402 disposed between the conductive terminal 304 and the conductive post. However, a distal portion of the conductive post (if left exposed) may be removed during the removal at 210, such as to reduce its height between proximal and distal ends. Alternatively, the removal at 210 can also be performed to remove the oxide and thus reveal the top surface of the semiconductor die 302. The removal at 210 can be implemented in any of a fabrication processes, such as by etching (e.g., wet or chemical) or mechanical removal (e.g., scraping). Because the sidewall portion 704 is aligned with the output periphery of the conductive terminal 304, the resulting seed layer 502 and barrier layer 402 between the conductive post 702 and the conductive terminal 304 likewise has an outer periphery that is approximately aligned with the outer periphery of the conductive terminal 304.

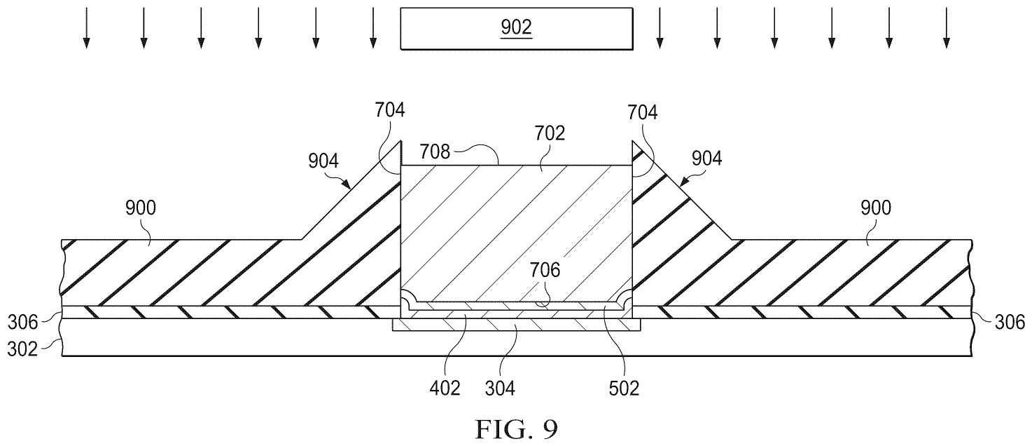

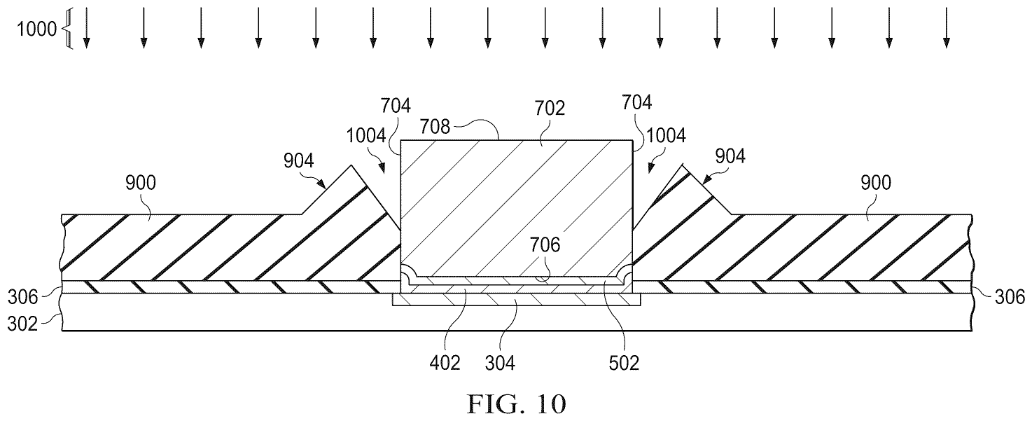

At 212, the method 200 includes forming a passivation layer over the surface of the semiconductor substrate and surrounding the sidewall portion of the conductive post. For example, as shown in FIG. 9, a passivation layer 900 can be formed on the semiconductor die 302 by depositing a dielectric material (e.g., also referred to as an electrically insulating film or material), such as a PI material. The passivation layer 900 can be formed by spin coating the PI on in any of a variety of different ways. The PI material can be selected from any of a variety of polyimides to provide dielectric characteristics and mechanical sturdiness to the IC device 300. In an example, the PI material is patterned through a reticle (e.g., a mask) 902. The reticle is configured to offset the application of the electrically PI material outwardly a distance from the sidewall portion 704 of the conductive post 702 (e.g., an offset ranging from about 8 μm to about 12 μm. The reticle is further configured to block the PI material from covering the conductive post 702 while allowing substantially free flow of the PI material onto the surface of the semiconductor die between respective posts. The passivation layer 900 includes a proximal portion adjacent the semiconductor die 302 and extends from the semiconductor substrate to terminate in a distal portion that is spaced apart from the semiconductor substrate defining a thickness for the passivation layer. The reticle 902 can be configured to control application of the PI material for a single die or a multi-die reticle can be used. The reticle 902 can be stepped across the wafer surface for applying the PI material to each die of the wafer. As shown in FIG. 9, a greater volume of the PI material can form within a region 904 along the sidewall 704 of the conductive post 702 (e.g., providing an increased thickness in the region 904). Additionally, as shown in FIG. 10, the applied PI material can be cured, shown at 1000, such as by heating, to form a hardened passivation layer 900 surrounding the sidewall portion 704 of the conductive post 702. For example, the curing can include heating to a temperature ranging from about 220° C. to about 380° C. depending on the type or PI material being used. The region 904 of the passivation layer 900 in which the increased volume accumulated has an increased thickness compared to the passivation layer at locations spaced away from the conductive post 702. Additionally, the curing the PI material causes contraction (e.g., shrinking) of the PI material that can further pull the PI material within a distal portion of the region 904 away from the sidewall 704 to define a gap 1004 extending between a radially inner periphery (e.g., edge) of the distal portion of the region 904 of the passivation layer 900 and an adjacent portion of the outer periphery of the sidewall 704 of the conductive post 702. In the example of FIG. 9, the gap has a generally triangular cross section, in which the distance between the PI material and the sidewall portion 704 is largest at a distal most portion of the gap and tapers inwardly (in a direction towards the sidewall portion) and axially towards the semiconductor die 302.

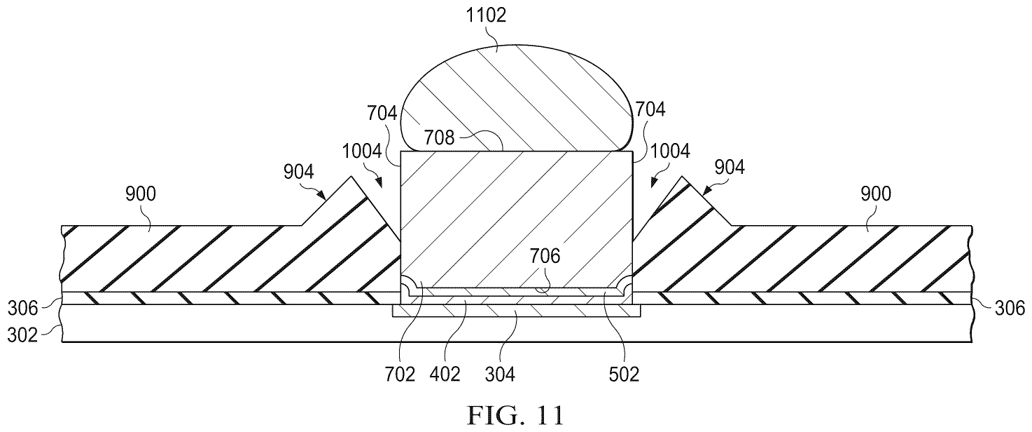

At 214, the method 200 includes forming a solder bump on the distal end of the conductive post. For example, as shown in FIG. 11, a solder bump 1102 of a flowable electrically conductive material can be applied to the distal end 708 of the conductive post 702. For example, the bump can be applied by stencil printing (e.g., through a stencil), electroplating solder jetting, controlled collapse chip connection new process (C4NP), or another solder transfer technology, which can depend on the material being applied and the diameter of the distal end 708. The solder material can be any of a variety of standard soldering materials (e.g., tin-silver-copper (SAC) or Sn—Ag). After the solder bump material has been applied, the material can be reflowed (e.g., by heating) to provide the solder bump 1102 a desired semispherical shape, as shown in FIG. 11.

Accordingly, upon forming the solder bump 1102 on the conductive post 702, the fabrication of the IC device 300 described herein can be considered complete. In an example where the method 200 is part of an WLP process, at 216, the method 200 includes singulating the wafer to provide respective dies. Additional packaging processes can be performed on the respective dies depending on the packaging technology. The fabrication method 200, as further described above with respect to FIGS. 3-11, thus demonstrate a manner for reducing formation of a resistive film between the conductive terminal structure 304 and the PI layer 900 that can result in an undesirable increase in resistance between the conductive post 212 and the semiconductor die 202. Additionally, because the conductive posts can be electroplated onto the pads (e.g., within a mask), the approach described herein can provide the distal end of the conductive posts an increased surface area to receive respective solder bumps, which can further increase the shear strength of the bumps.

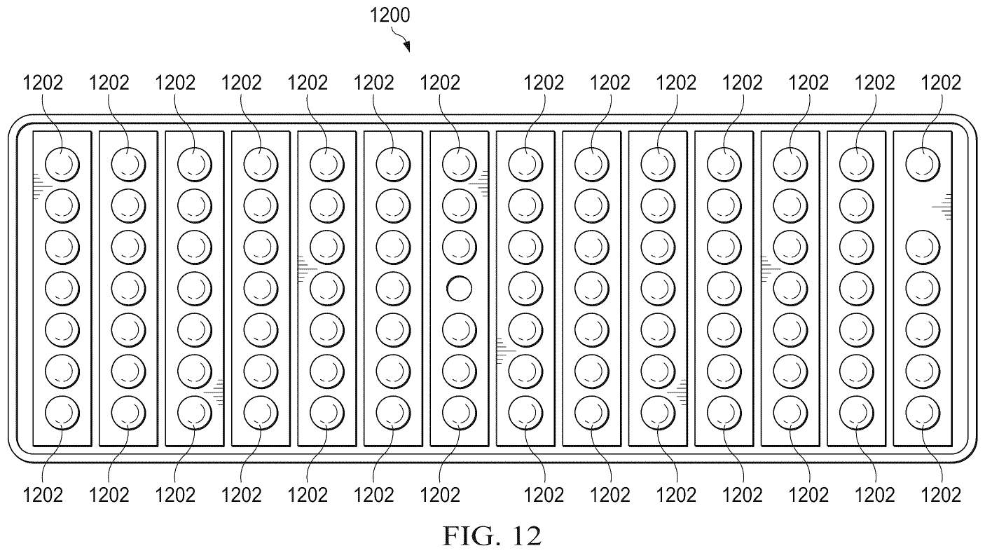

FIG. 12 is a plan view of an IC device 1200 having a plurality of pillar and solder bump structures 1202 formed thereon. Each of the pillar and solder bump structures 1202 can be formed according to the method 200 of FIG. 2. The IC device 1200 thus can include a plurality of instances of the pillar and solder bump structures described herein (see, e.g., FIGS. 1 and 11). For example, each of the pillar and solder bump structures 1202 can provide a respective input/output port that is coupled to terminals of active circuitry (e.g., through vias 132) formed in the IC device 1200. The distribution, arrangement, and number of bump structures 1202 on the IC device 1200 can depend on the configuration of the IC device and the intended application requirements of the IC device.

In this description, numerical designations “first”, “second”, etc. are not necessarily consistent with same designations in the claims herein and these numerical designations are used to simply distinguish one element from another.

Additionally, the term “couple” or variants thereof may cover connections, communications, or signal paths that enable a functional relationship consistent with this description. For example, if device A generates a signal to control device B to perform an action, then: (a) in a first example, device A is directly coupled to device B; or (b) in a second example, device A is indirectly coupled to device B through intervening component C if intervening component C does not alter the functional relationship between device A and device B, so device B is controlled by device A via the control signal generated by device A. In this description, the term “based on”means based at least in part on.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

Unless otherwise stated, “about,” “approximately,” or “substantially” preceding a value means within +/−10 percent of the stated value, or, if the value is zero, a reasonable range of values around zero.

Modifications are possible in the described embodiments, and other embodiments are possible, within the scope of the claims.

What is claimed is:

1. A method for fabricating an integrated circuit (IC) device, the method comprising:
forming a barrier layer over a surface of a semiconductor substrate and a conductive terminal in the surface;
forming a conductive seed layer over the barrier layer and at least a portion of the surface of the semiconductor substrate;
forming a conductive post over the seed layer, in which the conductive post includes a sidewall portion extending from a proximal end at the seed layer to terminate in a distal end spaced apart from the seed layer; and
forming a passivation layer over the surface of the semiconductor substrate and surrounding the sidewall portion of the conductive post.

2. The method of claim 1, wherein the passivation layer comprises polyimide.

3. The method of claim 1, wherein forming the passivation layer comprises:
applying an electrically insulating dielectric material over the surface of the semiconductor substrate at an offset from the sidewall portion of the conductive post; and
curing the electrically insulating dielectric material surrounding the sidewall portion of the conductive post.

4. The method of claim 3, wherein the electrically insulating dielectric material is applied through a reticle configured to offset the electrically insulating dielectric material outwardly from the sidewall portion of the conductive post.

5. The method of claim 3, wherein a greater volume of electrically insulating dielectric material forms within a region of the passivation layer adjacent and surrounding the sidewall portion of the conductive post to provide the passivation layer an increased thickness in the region compared to at a location of the passivation layer spaced apart from the region.

6. The method of claim 5, wherein curing the electrically insulating dielectric material causes shrinkage of the electrically insulating dielectric material to form a gap between a radially inner periphery of the region of the passivation layer and an adjacent portion of the sidewall portion of the conductive post.

7. The method of claim 1, wherein prior to applying the passivation layer, the method includes removing the seed layer that is located radially outwardly from the conductive post from the semiconductor substrate.

8. The method of claim 1, wherein forming the conductive post comprises:
forming a photoresist layer over the seed layer;
removing a portion of the photoresist layer to form an opening to expose a portion of the seed layer overlying the conductive terminal;
forming the conductive post within the opening; and
removing a remaining portion photoresist layer.

9. The method of claim 8, wherein conductive post is formed by electroplating a conductive material within the opening on the exposed portion of the seed layer.

10. The method of claim 1, further comprising forming a solder bump on the distal end of the conductive post.

11. An integrated circuit device, comprising:
a semiconductor substrate having a surface that includes a conductive terminal;
a barrier layer over the conductive terminal, in which the barrier layer has an outer periphery that is aligned with or spaced inwardly from an outer periphery of the conductive terminal;
a conductive post extending outwardly from the barrier layer to terminate in a distal end, in which the conductive post includes a sidewall having an outer periphery that is substantially aligned with or spaced inwardly from the outer periphery of the barrier layer; and
a passivation layer over the surface and surrounding a proximal portion of the conductive post, in which the passivation layer does not directly contact the conductive terminal.

12. The integrated circuit device of claim 11, wherein the passivation layer comprises polyimide.

13. The integrated circuit device of claim 11, wherein the conductive post has a substantially uniform diameter between the proximal and distal ends thereof, and a radially inner periphery of the passivation layer surrounding the conductive post is aligned with or located radially outwardly from the sidewall of the conductive post.

14. The integrated circuit device of claim 11, wherein a region of the passivation layer adjacent and surrounding the sidewall of the conductive post has an increased thickness relative to a thickness of the passivation layer spaced further apart from the sidewall of the conductive post.

15. The integrated circuit device of claim 14, further comprising a gap between a radially inner periphery of a distal portion of the region of the passivation layer and an adjacent portion of the sidewall of the conductive post.

16. The integrated circuit device of claim 11, further comprising a solder bump on the distal end of the conductive post.

17. The integrated circuit device of claim 11, further comprising a conductive seed layer over the barrier layer, in which a proximal end of conductive post contacts the seed layer and the conductive post extends outwardly from seed layer.

18. The integrated circuit device of claim 17, wherein the conductive post and the seed layer comprise a same conductive material.

19. The integrated circuit device of claim 11, further comprising:
active circuitry formed in the semiconductor substrate; and
a conductive via coupled between the active circuitry and the conductive terminal.

20. An integrated circuit device, comprising:
a semiconductor substrate that includes a plurality of conductive pads distributed across a surface of the semiconductor substrate within a conductive layer of the semiconductor substrate;
a barrier layer having a plurality of barrier members, in which each of the barrier members is over a respective one of the conductive pads, and each of the barrier members has an outer periphery that is substantially aligned with an outer periphery of the respective conductive pad;
a plurality of conductive posts, in which each conductive post is over a respective one of the conductive pads and extends outwardly from a proximal end at the barrier layer to terminate in a distal end thereof over the respective conductive pad, and each conductive post has a periphery at the proximal end thereof that is substantially aligned with or spaced radially inwardly from the outer periphery of the respective conductive pad;
a solder bump on the distal end of each conductive post, in which each respective solder bump is coupled to the respective conductive pad through a respective conductive post and a respective barrier member; and
a passivation layer over the surface of the semiconductor substrate surrounding a proximal portion of each of the conductive posts, in which the passivation layer does not directly contact the conductive pad.

21. The integrated circuit device of claim 20, wherein a region of the passivation layer adjacent and surrounding each of the conductive posts has an increased thickness relative to a thickness of the passivation layer located at a spaced apart location between adjacent conductive posts.

22. The integrated circuit device of claim 21, further comprising a gap between a radially inner periphery of a distal portion of the region of the passivation layer, which is spaced apart from the surface of the semiconductor substrate, and an adjacent portion of the periphery of a respective conductive post that the region of the passivation layer surrounds.
